(19) United States
(12) Patent Application Publication
(10) Pub. No.: US 2026/0135056 A1
(43) Pub. Date: May 14, 2026

(54) MULTI-CHARGED PARTICLE BEAM IRRADIATION APPARATUS AND MULTI-CHARGED PARTICLE BEAM IRRADIATION METHOD

(71) Applicant: NuFlare Technology, Inc., Yokohama-shi (JP)

(72) Inventors: Takanao TOUYA, Kawasaki-shi (JP); Hirofumi MORITA, Setagaya-ku (JP); Satoshi NAKAHASHI, Yokohama-shi (JP)

(73) Assignee: NuFlare Technology, Inc., Yokohama-shi (JP)

(21) Appl. No.: 19/338,199

(22) Filed: Sep. 24, 2025

(30) Foreign Application Priority Data
Nov. 13, 2024 (JP) 2024-198394

(51) Int. Cl. H01J 37/04; H01J 37/317

(52) U.S. Cl. CPC H01J 37/045; H01J 37/3174

(57) ABSTRACT

In one embodiment, a multi-charged particle beam irradiation apparatus includes a plurality of blankers blanking-deflecting each beam in a multi-beam, a stopping aperture substrate blocking the beam blanking-deflected to achieve a beam-OFF state by the plurality of blankers, the stopping aperture substrate including an opening through which a beam in a beam-ON state passes, a front stage electrode disposed upstream of the stopping aperture substrate in a beam optical path, and a potential control circuit forming an electric field in a direction from the front stage electrode to the stopping aperture substrate. An inner diameter d of the front stage electrode is determined based on a distance r1 from a center of the opening to a position at which the blanking-deflected beam collides with the stopping aperture substrate, and a spread radius r2 of the multi-beam at a height position of an upper end of the front stage electrode.

### CROSS REFERENCE TO RELATED APPLICATION

This application is based upon and claims benefit of priority from the Japanese Patent Application No. 2024-198394, filed on Nov. 13, 2024, the entire contents of which are incorporated herein by reference.

### FIELD

The present invention relates to a multi-charged particle beam irradiation apparatus and a multi-charged particle beam irradiation method.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. High-precision original patterns are written by an electron beam writing apparatus, and so-called electron beam lithography technique is used.

Some writing apparatuses use a multi-beam, for example. As compared to when writing is performed with a single electron beam, use of a multi-beam allows many beams to be emitted at a time, thus the throughput can be significantly improved. In a multi-beam writing apparatus, for example, an electron beam emitted from an electron source is passed through a shaping aperture array substrate having multiple openings to form a multi-beam, and each beam is individually blanking-controlled by a blanking aperture array substrate. The beam blanking-deflected by the blanking aperture array substrate is blocked by a stopping aperture substrate, and the beam not deflected is passed through an opening of the stopping aperture substrate, and a desired position on a sample is irradiated with the beam.

When the blanking-deflected beam is blocked by the stopping aperture substrate, secondary electrons (including reflected electrons) are released from the stopping aperture substrate. Due to the electric field of the electron cloud of secondary electrons, the beam is deflected, and the beam irradiation position on the sample is shifted. For this reason, a material causing less emission amount of secondary electrons has been used for the stopping aperture substrate.

However, there is a limit in reduction of the secondary electrons emitted from the stopping aperture substrate. Also, due to deterioration of the material for the stopping aperture substrate over time, the secondary electron emission rate varies with time. When the beam current is increased to improve the throughput, the emission amount of secondary electrons increases in proportion to the beam current, thus the effect of the electric field of secondary electrons on the beam is increased.

### BRIEF DESCRIPTION OF THE DRAWINGS

FIG. 1 is a schematic configuration diagram of a writing apparatus according to an embodiment of the present invention.

FIG. 2 is a plan view of a shaping aperture array substrate.

FIG. 3 is a schematic view of secondary electrons which are pulled back to a stopping aperture substrate.

FIG. 4 is a view for explaining the inner diameter of a front stage electrode.

### DETAILED DESCRIPTION

In one embodiment, a multi-charged particle beam irradiation apparatus includes a charged particle source that generates and emits a multi-beam, a plurality of blankers that blanking-deflects each beam in the multi-beam, a stopping aperture substrate that blocks the beam blanking-deflected to achieve a beam-OFF state by the plurality of blankers, the stopping aperture substrate including an opening through which a beam in a beam-ON state passes, a front stage electrode disposed upstream of the stopping aperture substrate in a beam optical path, and a potential control circuit that forms an electric field in a direction from the front stage electrode to the stopping aperture substrate by applying a predetermined electric potential to at least one of the stopping aperture substrate and the front stage electrode so that an electric potential of the stopping aperture substrate is higher than an electric potential of the front stage electrode. An inner diameter d of the front stage electrode is determined based on a distance r1 from a center of the opening to a position at which the blanking-deflected beam collides with the stopping aperture substrate, and a spread radius r2 of the multi-beam at a height position of an upper end of the front stage electrode.

Hereinafter, an embodiment of the present invention will be described based on the drawings. In the present embodiment, a configuration using an electron beam as an example of a charged particle beam will be described. The charged particle beam is not limited to an electron beam, and may be a beam using a charged particle beam, such as an ion beam. In the present embodiment, a multi-beam writing apparatus using multi-electron beams will be described as an example of a multi charged-particle beam irradiation apparatus. However, the multi-charged particle beam irradiation apparatus is not limited to the multi-beam writing apparatus, and the embodiment may be applied to a multi-beam inspection apparatus.

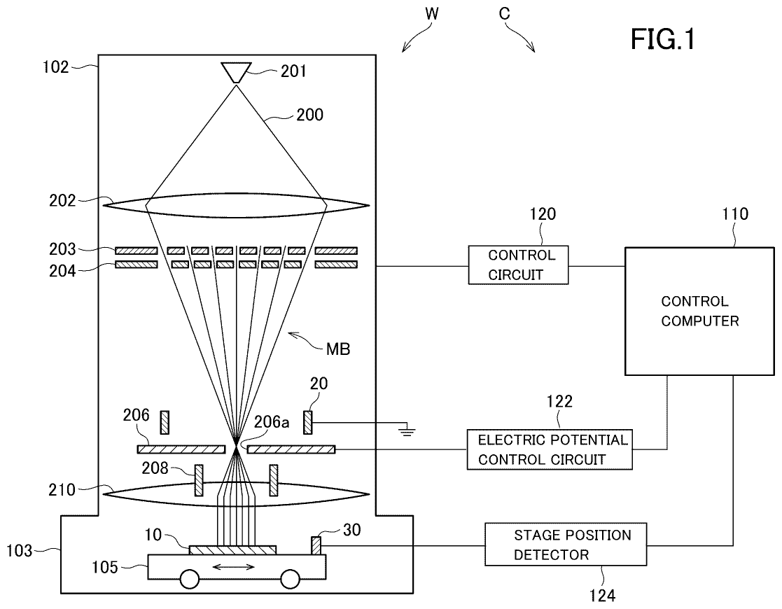

FIG. 1 is a schematic configuration diagram of a multi-beam writing apparatus according to an embodiment of the present invention. As illustrated in FIG. 1, the multi-beam writing apparatus includes a writer W and a controller C. The writer W includes an electron optical column 102 and a writing chamber 103. In the electron optical column 102, an electron source 201, a lens 202, a shaping aperture array substrate 203, a blanking aperture array substrate 204, a front stage electrode 20, a stopping aperture substrate 206, a deflector 208, and an objective lens 210 are disposed which constitute the electron optical system of the multi-beam writing apparatus.

In the writing chamber 103, an XY stage 105 movable in XY direction is disposed. The XY stage 105 may be movable in Z direction. On the XY stage 105, a substrate 10 as a writing target is disposed. The substrate 10 may refer to an exposure mask when a semiconductor device is fabricated, and a semiconductor substrate (silicon wafer) on which a semiconductor device is fabricated. In addition, the substrate 10 may refer to mask blanks coated with resist, on which nothing has been written.

On the XY stage 105, a mirror 30 for measuring the stage position is disposed.

The controller C includes a control computer 110, a control circuit 120, an electric potential control circuit 122 and a stage position detector 124. The stage position detector 124 emits a laser, receives light reflected from the mirror 30, and detects the position of the XY stage 105 by the principle of laser interferometry.

FIG. 1 illustrates the components necessary for explaining the embodiment, and other components are not illustrated.

FIG. 2 is a conceptual view of the configuration of the shaping aperture array substrate 203. In the shaping aperture array substrate 203 of FIG. 2, openings (first openings) 203a in p vertical (y direction) columns×q horizontal (x direction) rows (p, q>=2) are formed in a matrix form with a predetermined arrangement pitch. For example, the openings 203a in 512 columns×512 rows are formed. The openings 203a are formed in rectangular shapes having the same dimensions. The openings 203a may be circular. Part of an electron beam 200 passes through a corresponding one of these multiple openings 203a, thereby forming a multi-beam MB.

The blanking aperture array substrate 204 is provided below the shaping aperture array substrate 203, and passage holes (second openings) are formed corresponding to the arranged positions of the openings 203a of the shaping aperture array substrate 203. Each passage hole is provided with a blanker consisting of a set of two paired electrodes. One electrode of the blanker is fixed to the ground electric potential, and the other electrode is switched between the ground electric potential and another electric potential. Electron beams passing through respective passage holes are each independently deflected by a voltage applied to a corresponding one of blankers. In this manner, multiple blankers perform blanking deflection on corresponding beams in the multi-beam MB which has passed through the multiple openings 203a of the shaping aperture array substrate 203.

The electron beam 200 emitted from the electron source 201 (emitter) is refracted by the lens 202, and illuminates the entire shaping aperture array substrate 203. The electron beam 200 illuminates an area including the multiple (all) openings 203a. Part of the electron beam 200 passes through the multiple openings 203a of the shaping aperture array substrate 203, thereby forming a multi-beam MB including multiple individual beams. The multi-beam MB passes through corresponding blankers of the blanking aperture array substrate 204. The blankers each perform blanking control on a passing individual beam so that the beam is in ON state for a set writing time (irradiation time).

The multi-beam MB which has passed through the blanking aperture array substrate 204 forms a crossover by the focusing effect of the lens 202. The stopping aperture substrate 206 is disposed so that an opening 206a (a third opening) formed in the center thereof has substantially the same height position as that of the crossover.

Each beam deflected by a blanker of the blanking aperture array substrate 204 deviates from the position of the opening 206a of the stopping aperture substrate 206, and is blocked by the stopping aperture substrate 206. In contrast, each beam not deflected by a blanker of the blanking aperture array substrate 204 passes through the opening 206a of the stopping aperture substrate 206. In this manner, the stopping aperture substrate 206 blocks the beams which have been deflected to achieve a beam OFF state by respective blankers.

As already described, the stopping aperture substrate 206 is placed so that the opening 206a thereof has substantially the same height position as that of the crossover. At the crossover, the lateral spread of the beam is small, thus this placement is suitable for cutting the deflected beam to achieve a beam-OFF state. If the height position of the opening 206a is vertically displaced from the height position of the crossover, the multi-beam MB is widely spread at the height of the opening 206a position. Thus, a problem arises in the writing function and/or the writing performance, for example, beams (individual beams in part) are produced which are not sufficiently cut at the time of beam cut or beams (individual beams in part) are produced which continue to be cut.

The beam for one shot is formed by the beam which has passed through the stopping aperture substrate 206 since beam-ON until beam-OFF is achieved. Each beam in the multi-beam MB which has passed through the stopping aperture substrate 206 becomes an aperture image with a desired reduction ratio, of an opening 203a of the shaping aperture array substrate 203 by the objective lens 210, and is brought into focus on the substrate 10. The beams (the entire multi-beam) which have passed through the stopping aperture substrate 206 are collectively deflected by the deflector 208 in the same direction, and are emitted to respective irradiation positions of the beams on the substrate 10.

For example, when the XY stage 105 is continuously moved, the irradiation position of each beam is controlled by the deflector 208 so that the irradiation position follows the movement of the XY stage 105. The multi-beam MB emitted at once is ideally arranged with a pitch which is the product of the arrangement pitch of the multiple openings 203a of the shaping aperture array substrate 203 and the above-mentioned desired reduction ratio. The writing apparatus performs a writing operation by a raster scan method by which a shot beam is sequentially emitted continuously, and when a desired pattern is written, unnecessary beams are controlled at beam OFF by the blanking control.

In this writing apparatus, when a blanking-deflected beam is blocked by the stopping aperture substrate 206, secondary electrons are emitted from the stopping aperture substrate 206, and the secondary electrons have an effect on the beam irradiation position.

Thus, in the present embodiment, the front stage electrode 20 set to the ground electric potential is disposed above (front side in the beam traveling direction, upstream side of the beam optical path) the stopping aperture substrate 206, and the electric potential control circuit 122 applies a positive electric potential to the stopping aperture substrate 206.

Note that the front stage electrode 20 is disposed below (rear stage side in the beam traveling direction, downstream side of the beam optical path) the lens 202 and the blanking aperture array substrate 204 for forming the crossover at the height of the opening of the stopping aperture substrate 206.

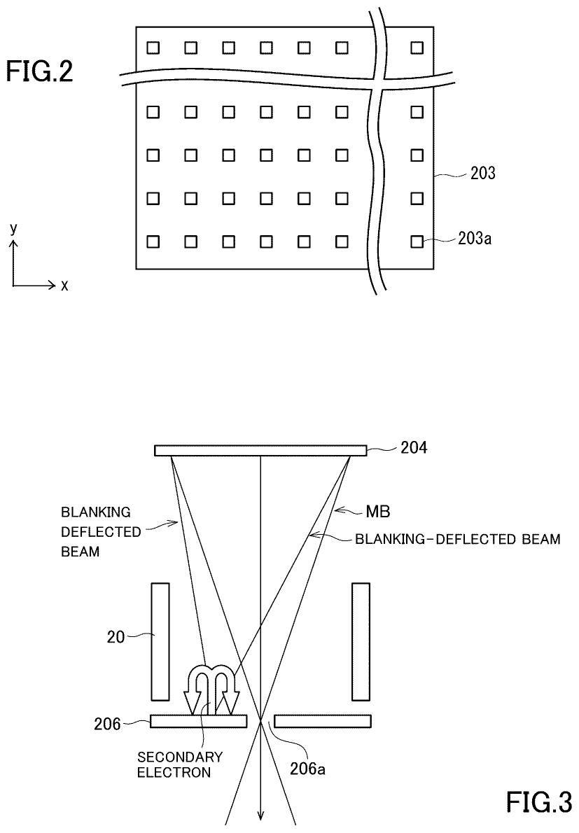

Consequently, an electric field is formed in the direction from the front stage electrode 20 to the stopping aperture substrate 206, thus as illustrated in FIG. 3, the secondary electrons emitted from the stopping aperture substrate 206 are pulled back to the stopping aperture substrate 206, therefore the effect of the secondary electrons on the beam can be reduced. Therefore, the accuracy of beam irradiation position can be improved. Because the secondary electrons are pulled back to the stopping aperture substrate 206 by control of the electric field, the effect varies little, and has a small variation with lapse of time.

The level of electric potential to be applied by the electric potential control circuit 122 is determined based on the beam current of the multi-beam, the material for the stopping aperture substrate 206, and the space between the stopping aperture substrate 206 and the front stage electrode 20.

The material for the stopping aperture substrate 206 is not limited to a specific one, and e.g., Ta which is a non-magnetic material may be used. The shape of the stopping aperture substrate 206 and the opening 206a is e.g., circular.

The shape of the front stage electrode 20 is not limited to a specific one, and for example, a cylindrical electrode may be used. The material for the front stage electrode 20 is not limited to a specific one, and e.g., Ti which is a non-magnetic material may be used.

The multi-beam MB is focused to the crossover at the same height position as that of the stopping aperture substrate 206, and the spread width becomes extremely small; however, the multi-beam MB passes through the blanking aperture array substrate 204 with an extremely large width, thus has spread to a relatively wide area in the vicinity of the front stage electrode 20 upstream of the stopping aperture substrate 206. Meanwhile, if the front stage electrode 20 has a small inner diameter, part of the spread multi-beam MB collides with the front stage electrode 20, which causes a problem in the writing. To prevent this, the incident multi-beam MB needs to pass through the front stage electrode 20 without colliding with the inner peripheral surface of the front stage electrode 20 in a cylindrical shape. For this purpose, the inner diameter d (diameter, bore diameter) of the front stage electrode 20 is set to the value represented by the following expression.

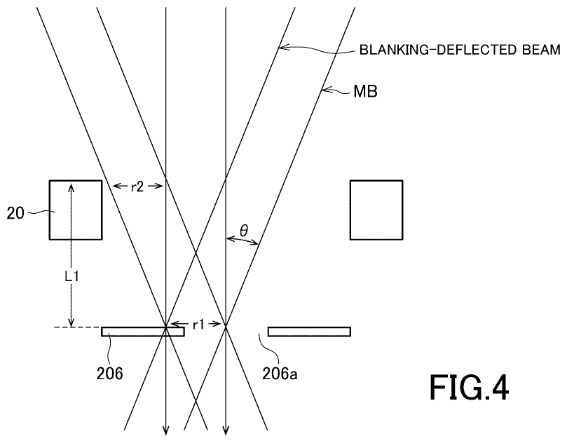

In the following expression, r1 is the distance from the center of the opening 206a of the stopping aperture substrate 206 to the position at which the blanking-deflected beam collides with the stopping aperture substrate 206, and r2 is the spread radius of the multi-beam MB at the height position of the upper end of the front stage electrode 20. For these, FIG. 4 illustrates an enlarged view of the vicinity of the stopping aperture substrate 206 and the front stage electrode 20.

$$The inner diameter d > 2 \times ( r 1 + r 2 )$$

In addition, let θ (unit rad) be a convergence semi-angle at the crossover of the multi-beam MB, and let L1 be the distance from the upper surface of the stopping aperture substrate 206 to the upper end of the front stage electrode 20, r2 is calculated by the following expression.

$$r 2 = θ \times L 1$$

In the above expression, due to the term r2, collision of a beam not blanked with the front stage electrode 20 is prevented. Furthermore, by adding the term r1, collision of a blanked beam with the front stage electrode 20 is prevented. Only the term r2 is sufficient if attention is focused on the beam necessary for writing; however, only with r2, the blanked beam may collide with the front stage electrode 20, causing a problem in that the beam is affected by the electron cloud of secondary electrons generated in the front stage electrode 20 due to the collision. Therefore, the term r1 to cope with prevention of collision of the blanked beam is necessary.

It is preferable that the center of the opening 206a of the stopping aperture substrate 206 and the cylindrical axis of the front stage electrode 20 in a cylindrical shape be located on the trajectory axis of the multi-beam.

In the above embodiment, the configuration has been described in which the front stage electrode 20 is set to the ground electric potential, and a positive electric potential is applied to the stopping aperture substrate 206; however, it is sufficient that an electric field be formed in the direction from the front stage electrode 20 to the stopping aperture substrate 206 by making the electric potential of the upper surface of the stopping aperture substrate 206 higher than the electric potential of the front stage electrode 20. For example, the stopping aperture substrate 206 may be set to the ground electric potential, and the potential control circuit 122 may apply a negative electric potential to the front stage electrode 20.

Alternatively, the potential control circuit 122 may apply a negative electric potential to the front stage electrode 20, and apply a positive electric potential to the stopping aperture substrate 206.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam irradiation apparatus comprising:
a charged particle source that generates and emits a multi-beam;
a plurality of blankers that blanking-deflects each beam in the multi-beam;
a stopping aperture substrate that blocks the beam blanking-deflected to achieve a beam-OFF state by the plurality of blankers, the stopping aperture substrate including an opening through which a beam in a beam-ON state passes;
a front stage electrode disposed upstream of the stopping aperture substrate in a beam optical path; and
a potential control circuit that forms an electric field in a direction from the front stage electrode to the stopping aperture substrate by applying a predetermined electric potential to at least one of the stopping aperture substrate and the front stage electrode so that an electric potential of the stopping aperture substrate is higher than an electric potential of the front stage electrode,
wherein an inner diameter d of the front stage electrode is determined based on a distance r1 from a center of the opening to a position at which the blanking-deflected beam collides with the stopping aperture substrate, and a spread radius r2 of the multi-beam at a height position of an upper end of the front stage electrode.

2. The multi-charged particle beam irradiation apparatus according to claim 1,
wherein let L1 be a distance from the stopping aperture substrate to the upper end of the front stage electrode, and let θ (unit rad) be a convergence semi-angle at a crossover of the multi-beam, then the spread radius r2 satisfies
$$r 2 = θ \times L 1 ,$$
the inner diameter d of the front stage electrode satisfies
$$d > 2 \times ( r 1 + r 2 ) .$$

3. The multi-charged particle beam irradiation apparatus according to claim 1,
wherein the potential control circuit applies a positive electric potential to the stopping aperture substrate, and
the front stage electrode is set to a ground electric potential.

4. The multi-charged particle beam irradiation apparatus according to claim 1,
wherein the potential control circuit applies a negative electric potential to the front stage electrode, and
the stopping aperture substrate is set to a ground electric potential.

5. The multi-charged particle beam irradiation apparatus according to claim 1,
wherein the potential control circuit applies a positive electric potential to the stopping aperture substrate, and applies a negative electric potential to the front stage electrode.

6. The multi-charged particle beam irradiation apparatus according to claim 1,
wherein the front stage electrode has a cylindrical shape.

7. The multi-charged particle beam irradiation apparatus according to claim 6,
wherein a shape of the opening of the stopping aperture substrate is circular.

8. The multi-charged particle beam irradiation apparatus according to claim 7,
wherein a center of the opening of the stopping aperture substrate and a cylindrical axis of the front stage electrode in a cylindrical shape are located on a trajectory axis of the multi-beam.

9. A multi-charged particle beam irradiation method comprising:
generating a multi-beam using a charged particle source;
blanking-deflecting each beam in the multi-beam using a plurality of blankers;
blocking a beam by a stopping aperture substrate, the beam being blanking-deflected to achieve a beam-OFF state by the plurality of blankers; and
forming an electric field in a direction from the front stage electrode to the stopping aperture substrate by applying a predetermined electric potential to at least one of the stopping aperture substrate and the front stage electrode so that an electric potential of the stopping aperture substrate is higher than an electric potential of the front stage electrode disposed upstream of the stopping aperture substrate in a beam optical path,
wherein let L1 be a distance from the stopping aperture substrate to the upper end of the front stage electrode, and let θ (unit rad) be a convergence semi-angle at a crossover of the multi-beam, then a spread radius r2 of the multi-beam at a height position of an upper end of the front stage electrode satisfies
$$r 2 = θ \times L 1 ,$$
let r1 be a distance between a center of an opening provided in the stopping aperture substrate to allow a beam in a beam-ON state to pass through the opening, and a position at which the blanking-deflected beam collides with the stopping aperture substrate, then an inner diameter d of the front stage electrode satisfies
$$d > 2 \times ( r 1 + r 2 ) .$$

10. The multi-charged particle beam irradiation method according to claim 9,
wherein a positive electric potential is applied to the stopping aperture substrate, and the front stage electrode is set to a ground electric potential.

11. The multi-charged particle beam irradiation method according to claim 9,
wherein a negative electric potential is applied to the front stage electrode, and the stopping aperture substrate is set to a ground electric potential.

12. The multi-charged particle beam irradiation method according to claim 9,
wherein a positive electric potential is applied to the stopping aperture substrate, and a negative electric potential is applied to the front stage electrode.
